(19) United States
(12) Patent Application Publication
(10) Pub. No.: US 2025/0240916 A1
(43) Pub. Date: Jul. 24, 2025

(54) SERVER

(71) Applicant: SHENZHEN ENVICOOL TECHNOLOGY CO., LTD., Shenzhen (CN)

(72) Inventors: Xiaoxin XU, Shenzhen (CN); Xiaolei AI, Shenzhen (CN)

(73) Assignee: SHENZHEN ENVICOOL TECHNOLOGY CO., LTD., Shenzhen (CN)

(21) Appl. No.: 18/806,016

(22) Filed: Aug. 15, 2024

(30) Foreign Application Priority Data
Jan. 19, 2024 (CN) 202410084487.X

(51) Int. Cl. H05K 7/20

(52) U.S. Cl. CPC H05K 7/20272; H05K 7/20254; H05K 7/20772

(57) ABSTRACT

A server includes a liquid cooling system, multiple first electronic components with a first function, and multiple second electronic components with a second function. The liquid cooling system includes multiple first cooling plates, multiple second cooling plates, a liquid distributor, and a liquid collector, each of the first electronic components is fitted against the corresponding first cooling plate, and each of the second electronic components is fitted against the corresponding second cooling plate. At least two first cooling plates are connected in series and/or in parallel between a first liquid distribution port of the liquid distributor and a first liquid collection port of the liquid collector, and at least two second cooling plates are connected in series and/or in parallel between a second liquid distribution port of the liquid distributor and a second liquid collection port of the liquid collector.

### CROSS REFERENCE TO RELATED APPLICATIONS

This application claims the priority to Chinese Patent Application No. 202410084487.X titled “SERVER”, filed with the China National Intellectual Property Administration on Jan. 19, 2024, which is incorporated herein by reference in its entirety.

### FIELD

The present disclosure relates to the technical field of electronic devices, and in particular to a server.

### BACKGROUND

For a server or other electronic devices, it is generally necessary to dissipate heat from heating elements, such as GPU (graphics processing unit), CPU (central processing unit), switch and so on. The conventional air-cooling system, due to its large size, cannot be applied to some electronic devices. At present, a liquid cooling system generally has a relatively small size, occupying a relatively small space especially at the location of the heating element.

Generally, various types of electronic components are provided in the server, and the number of these various types of electronic components is large, so the liquid cooling system needs to be provided with multiple cooling plates. With a long-term practical research by the inventor, it has been found that the conventional liquid supply is too dispersed, causing the liquid supply pipes being messy, which increases the difficulty of maintenance, and results in large friction between the liquid supply pipes.

Therefore, the problem to be solved by those skilled in the art is that the liquid-supply effect of centralized liquid supply to cooling plates arranged at various electronic components is poor.

### SUMMARY

In view of this, an object of the present disclosure is to provide a server, which can effectively solve the problem of the poor liquid-supply effect of centralized liquid supply to cooling plates arranged at various electronic components.

In order to achieve the above object, technical solutions are provided according to the present disclosure as follows.

A server includes a liquid cooling system; multiple first electronic components, each of which has a first function; and multiple second electronic components, each of which has a second function, where the liquid cooling system includes multiple first cooling plates in one-to-one correspondence with the multiple first electronic components, multiple second cooling plates in one-to-one correspondence with the multiple second electronic components, a liquid distributor, and a liquid collector, each of the multiple first electronic components is fitted against the corresponding first cooling plate, and each of the multiple second electronic components is fitted against the corresponding second cooling plate, at least two of the multiple first cooling plates are connected in series and/or in parallel between a first liquid distribution port of the liquid distributor and a first liquid collection port of the liquid collector, and at least two of the multiple second cooling plates are connected in series and/or in parallel between a second liquid distribution port of the liquid distributor and a second liquid collection port of the liquid collector.

In the above server, the multiple first cooling plates and the multiple second cooling plates are connected in series or in parallel, which can effectively reduce the number of ports in the liquid collector and the liquid distributor. In addition, the cooling plates provided for the electronic components with different functions are connected in series or in parallel, making it possible to centralizedly adjust and control the flow so as to better balance different heat dissipation needs of different types of electronic components. Therefore, the centralized heat-dissipation of the electronic components with corresponding functions can be better controlled through ports, thereby improving overall heat dissipation efficiency. In addition, since electronic components with the same function are generally mounted in a centralized manner, with the above arrangement, the distribution of connection pipelines can be more orderly. In summary, the server can effectively solve the problem of the poor effect of centralized liquid-supply to cooling plates arranged at various electronic components.

In a technical solution, the multiple first electronic components are arranged in multiple rows and/or multiple columns, the first cooling plates in each of the multiple rows are arranged in series or in parallel, and the first cooling plates in each of the multiple columns are arranged in series or in parallel; and/or the multiple second electronic components are arranged in multiple rows and/or multiple columns, the second cooling plates in each of the multiple rows are arranged in series or in parallel, and the second cooling plates in each of the multiple columns are arranged in series or in parallel.

In a technical solution, the number of the first liquid distribution port is plural, and the number of the first liquid collection port is plural, each of the first liquid distribution ports together with a corresponding one of the first liquid collection ports form a pair of first liquid distribution port and first liquid collection port; the multiple first electronic components are arranged in multiple rows and multiple columns, the first cooling plates in each of the multiple rows are arranged in parallel, and the first cooling plates in each of the multiple rows are in communication with the corresponding pair of first liquid distribution port and first liquid collection port; the multiple second electronic components are arranged in one column, and the multiple second cooling plates are connected in series, where the multiple first electronic components are GPUs, and the multiple second electronic components are switches.

In a technical solution, the liquid collector extends in a column direction and is provided with multiple ports in sequence, which serves as the first liquid collection ports and the second liquid collection port respectively, and the liquid distributor extends in a column direction and is provided with multiple ports in sequence, which serves as the first liquid distribution ports and the second liquid distribution port respectively, where each of the first liquid collection ports and a corresponding one of the first liquid distribution ports are connected to a corresponding row of first cooling plates of the multiple first cooling plates.

In a technical solution, both the liquid collector and the liquid distributor are arranged at sides of the multiple second electronic components away from the multiple first electronic components, and the multiple ports of the liquid collector are arranged staggeredly with respect to the multiple ports of the liquid distributor along the column direction.

In a technical solution, the multiple first cooling plates and the multiple second cooling plates are in communication with the liquid collector and the liquid distributor through multiple guide tubes, and each of the first liquid distribution port, the first liquid collection port, the second liquid distribution port, and the second liquid collection port is in communication with the corresponding guide tube through a shut-off assembly; the shut-off assembly includes a first connection device and a second connection device that are detachable and separatable from each other, the first connection device is arranged at an orifice of the corresponding guide tube and blocks the guide tube when being disassembled from the second connection device, and the second connection device is arranged at the liquid distributor or the liquid collector and blocks the corresponding port when being disassembled from the first connection device.

In a technical solution, each of the multiple guide tubes is provided with a first detector extending along the guide tube, to detect whether leakage at the guide tube; and each of the multiple first cooling plates and the multiple second cooling plates is provided with a second detector, to detect leakage at the corresponding first cooling plate or the corresponding second cooling plate, a part of the multiple first detectors and a part of the multiple second detectors, corresponding to a part of the multiple guide tubes and a part of the multiple first cooling plates which are connected between the first liquid collection port and the first liquid distribution port, are connected in series to form a circuit; another part of the multiple first detectors and another part of the multiple second detectors, corresponding to another part of the multiple guide tubes and a part of the multiple second cooling plates which are connected between the second liquid collection port and the second liquid distribution port, are connected in series to form another circuit; the server further includes a collector for collecting an on/off state of each circuit.

In a technical solution, a protective outer tube is sleeved on an outer side of the guide tube, and the first detector is positioned between the guide tube and the protective outer tube.

In a technical solution, the server further includes a trough body with an upward opening and a cover that for covering the opening of the trough body, where each of the multiple first cooling plates and the multiple second cooling plates includes a heated plate and a cover plate, a window is provided at a bottom of the trough body, and a periphery of the heated plate is sealedly connected to a periphery of the window, a gap is formed between a periphery of the cover plate and inner walls of the trough body, so that a liquid leaking from a sealing joint between the heated plate and the cover plate is able to flow to one side of the cover plate away from the heated plate through the gap; the second detector is a sheet-like detector arranged on the cover plate.

In a technical solution, the server further includes a collection box, where the shut-off assembly, the liquid distributor, and the liquid collector are arranged inside the collection box; a side, away from the multiple first electronic components, of an inner lower surface of the collection box is inclined downwards and is provided with a detector for detecting leakage.

### BRIEF DESCRIPTION OF THE DRAWINGS

For more clearly illustrating embodiments of the present application or the technical solutions in the conventional technology, drawings referred to describe the embodiments or the conventional technology will be briefly described hereinafter. Apparently, the drawings in the following description are only some examples of the present application, and for those skilled in the art, other drawings may be obtained based on these drawings without any creative efforts.

FIG. 1 is a schematic cross-sectional view showing the structure of a server according to an embodiment of the present disclosure;

FIG. 2 is a schematic view showing the overall structure of the server according to the embodiment of the present disclosure; and

FIG. 3 is a schematic structural view of a portion where a cooling plate is located according to an embodiment of the present disclosure.

Reference numerals:

| | | | |
|---|---|---|---|
| 1 | first electronic component, | 2 | second electronic component, |
| 3 | first cooling plate, | 4 | second cooling plate, |
| 5 | liquid distributor, | 6 | liquid collector, |
| 7 | guide tube, | 8 | shut-off assembly, |
| 9 | trough body, | 10 | cover, |
| 11 | collection box. | | |

### DETAILED DESCRIPTION OF THE EMBODIMENTS

A server is provided in embodiments of the present disclosure, which can effectively solve the technical problem that the effect of centralized liquid-supply to cooling plates for various electronic components is poor.

Technical solutions according to the embodiments of the present application will be described clearly and completely as follows in conjunction with the accompany drawings in the embodiments of the present application. It is obvious that the described embodiments are only a part of the embodiments according to the present application, rather than all of the embodiments. All the other embodiments obtained by those skilled in the art based on the embodiments in the present application without any creative work belong to the scope of protection of the present application.

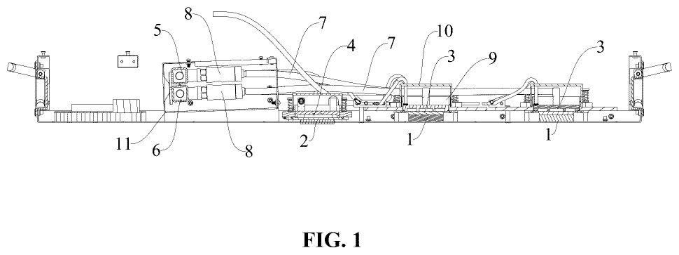

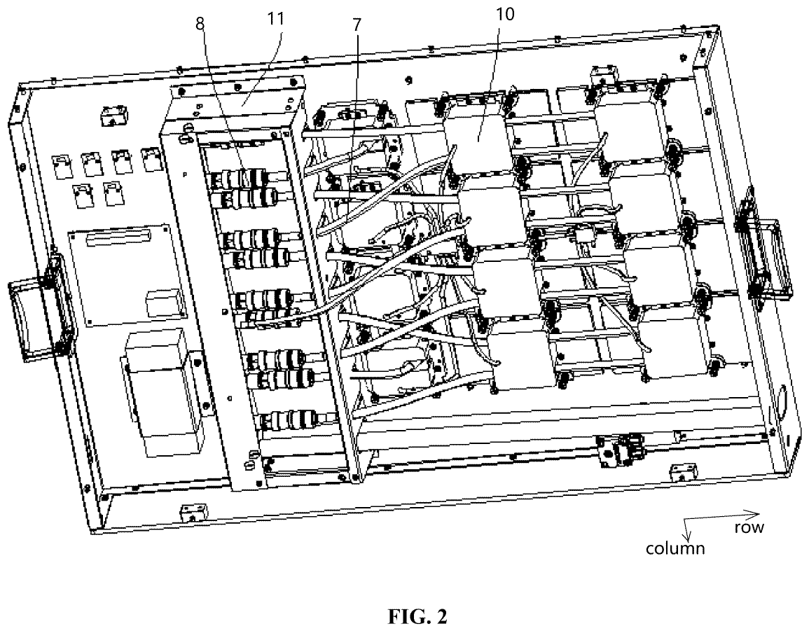

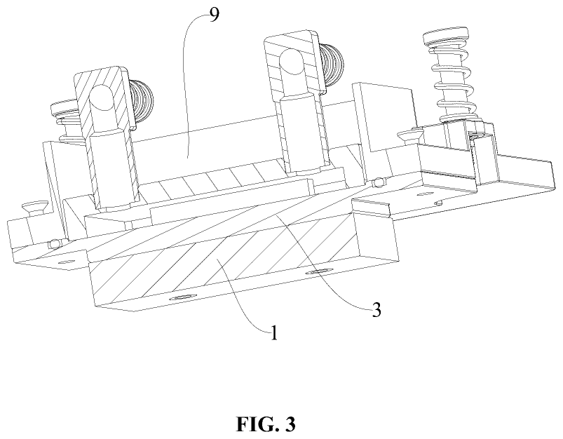

Referring to FIG. 1 to FIG. 3, where FIG. 1 is a schematic cross-sectional view showing the structure of a server according to an embodiment of the present disclosure, FIG. 2 is a schematic view showing the overall structure of the server according to the embodiment of the present disclosure, and FIG. 3 is a schematic structural view of a portion where a cooling plate is located according to an embodiment of the present disclosure. Herein, FIG. 1 shows the orientation of the server in use, where a direction perpendicular to the plane of the cooling plate is defined as a height direction of the server, i.e., an up-down direction; and FIG. 2 is actually a top view of the server in use, where a row direction is along a length direction of the server, and a column direction is along a width direction of the server.

A server is provided in an embodiment of the present disclosure. Specially, the server mainly includes a liquid cooling system, multiple first electronic components 1, and multiple second electronic components 2. The first electronic component 1 has a first function, and the second electronic component 2 has a second function, where the first function is different from the second function, that is, the first electronic component 1 and the second electronic component 2 have different functions. For example, one of the first electronic component 1 and the second electronic component 2 is a CPU while the other is a GPU.

The liquid cooling system includes multiple cooling plates, a liquid distributor 5, and a liquid collector 6. Two ends of each of the multiple cooling plates are in direct or indirect communication with the liquid distributor 5 or the liquid collector 6, respectively. The liquid distributor 5 is configured to be in communication with an inlet manifold, and the liquid collector 6 is configured to be in communication with an outlet manifold. After entering the liquid distributor 5 from the inlet manifold, the liquid is distributed into the multiple cooling plates via the liquid distributor 5. After absorbing heat from the electronic components, the liquid in the multiple cooling plates flows to the liquid collector 6 to be discharged to the outlet manifold. A guide tube 7 or another structure with liquid guide passage is provided for communication between the multiple cooling plates, communication between the liquid distributor 5 and the corresponding cooling plates, and communication between the liquid collector 6 and the corresponding cooling plates. Specifically, multiple guide tubes 7 are provided for the above communications.

To facilitate illustration, one part of the multiple cooling plates are referred to as first cooling plates 3, and the other part of the multiple cooling plates are referred to as the second cooling plates 4. The first cooling plates 3 are in one-to-one correspondence with the multiple first electronic components 1, and the second cooling plates 4 are in one-to-one correspondence with the multiple second electronic components 2. Each of the first electronic components 1 is fitted against the corresponding first cooling plate 3 for heat dissipation, and each of the second electronic components 2 is fitted against the corresponding second cooling plate 4 for heat dissipation.

At least two first cooling plates 3 may be connected in series and/or in parallel between

a first liquid distribution port of the liquid distributor 5 and a first liquid collection port of the liquid collector 6. The at least two first cooling plates 3 may all be connected in series, or may all be connected in parallel In the case that three or more first cooling plates 3 are provided, the connection manner may be some of the three or more first cooling plates 3 being connected in series, while the rest of the three or more first cooling plates 3 being connected in parallel. For example, in case of there're three cooling plates 3, two of them are connected in parallel and are then connect to the rest one in series.

At least two second cooling plates 4 may be connected in series and/or in parallel between a second liquid distribution port of the liquid distributor 5 and a second liquid collection port of the liquid collector 6. The specific manner of connection in series and/or in parallel may refer to the above description.

In the above server, the multiple first cooling plates 3 are connected in series or in parallel and the multiple second cooling plates 4 are connected in series or in parallel, which can effectively reduce the number of ports provided on the liquid distributor and liquid collector. In addition, with this arrangement, the cooling plates corresponding to the electronic components having one function are connected in series or in parallel, and the cooling plates corresponding to the electronic components having another function are connected in series or in parallel, which can centralizedly adjust and control the flow so as to better balance different heat dissipation needs of different types of electronic components. In this way, the centralized heat-dissipation of the electronic components with corresponding functions can be better controlled through ports, thereby improving overall heat dissipation efficiency. In addition, since the electronic components with the same function are generally mounted in a centralized manner, the above arrangement facilitates orderly distribution of the pipelines. In summary, the server can effectively solve the problem of the poor liquid-supply effect of centralized liquid supply to cooling plates arranged at various electronic components.

In some embodiments, the electronic components with the same function are generally arranged in multiple rows and/or multiple columns, that is, the multiple electronic components are arranged in multiple rows and a single column, or in a single row and multiple columns, or in multiple rows and multiple columns, to facilitate wiring.

Preferably, when the multiple first electronic components 1 are arranged in multiple rows and/or multiple columns, the first cooling plates 3 in each row are arranged in series or in parallel, and the first cooling plates 3 in each column are arranged in series or in parallel; and/or, when the multiple second electronic components 2 are arranged in multiple rows and/or multiple columns, the second cooling plates 4 in each row are arranged in series or in parallel, and the second cooling plates 4 in each column are arranged in series or in parallel.

Specifically, in a case that the multiple first electronic components 1 are arranged in multiple rows and in a single column, the first cooling plates 3 in the single column are arranged in series or in parallel. In a case that the multiple first electronic components 1 are arranged in a single row and multiple columns, the first cooling plates 3 in the single row are arranged in series or in parallel. In a case that the multiple first electronic components 1 are arranged in multiple rows and multiple columns, the first cooling plates 3 in each row are arranged in series or in parallel, and the first cooling plates 3 in each column are arranged in series or in parallel; when the first cooling plates 3 in each row are arranged in series or in parallel, the first cooling plates 3 in a same row can be connected between a corresponding pair of first liquid distribution port and first liquid collection port. It should be noted that, multiple first liquid distribution ports are provided on the liquid distributor, multiple first liquid collection ports are provided on the liquid collector, the first liquid distribution ports and the first liquid collection ports are in one-to-one correspondence, and each pair of first liquid distribution port and first liquid collection port is corresponding to one row of the multiple rows of first electronic components. The connection manner among multiple second cooling plates 4 may refer to any one of the above connection manners of the first cooling plates 3.

In some embodiments, specially, multiple first electronic components 1 may be arranged in multiple rows and multiple columns, the first cooling plates 3 in each row are connected in parallel, and the first cooling plates 3 in each row are connected between a corresponding pair of first liquid distribution port and first liquid collection port. That is, one pair of first liquid distribution port and first liquid collection port corresponds to a first row of the multiple rows of first cooling plates 3 while another pair of first liquid distribution port and first liquid collection port corresponds to a second row of the multiple rows of first cooling plates 3.

Specifically, the multiple second electronic components 2 are arranged in one column, and the second cooling plates 4 are connected in series. Specifically, the first electronic component 1 mentioned above may be a GPU, and the second electronic component 2 may be a switch. Generally, the switch has less heat to be dissipated, and the heat dissipation demand can be well satisfied by a series connection. By contrast, the GPU has a higher heat dissipation demand, and with the arrangement of multiple rows and multiple columns, not only the distribution is easier, but also the guide tubes 7 can be better arranged.

In some embodiments, the liquid collector 6 extends in the column direction and is provided with multiple ports in sequence, i.e., the first liquid collection ports and the second liquid collection port; the liquid distributor 5 also extends in the column direction and is provided with multiple ports in sequence, i.e., the first liquid distribution ports and the second liquid distribution port. A pair of first liquid collection port and first liquid distribution port is connected to the first cooling plates 3 in a corresponding row.

In some embodiments, the number of columns of first cooling plates 3 is less than the number of rows of first cooling plates 3, so that there are fewer first cooling plates 3 connected between the corresponding pair of first liquid distribution port and first liquid collection port. It should be noted that, in this application, the cooling plates being connected between the liquid distribution port and the liquid collection port refers to a communication relationship rather than a positional relationship, that is, inlets of the cooling plates are directly or indirectly in communication with the liquid distribution port, and outlets of the cooling plates are directly or indirectly in communication with the liquid collection port. Herein, to facilitate description, each of the first cooling plates 3 and the second cooling plates 4 can be referred to as a cooling plate, each of the first liquid collection ports and the second liquid collection port can be referred to as a liquid collection port, and each of the first liquid distribution ports and the second liquid distribution port can be referred to as a liquid distribution port.

In some embodiments, both the liquid collector 6 and the liquid distributor 5 may be arranged at a side of the second electronic component 2 away from the first electronic component 1, so that the second electronic component 2 can be in communication at the closest position.

Alternatively, both the liquid collector 6 and the liquid distributor 5 may be arranged at

a side of the first electronic component 1 away from the second electronic component 2, which can effectively shorten the guide tubes 7.

In some embodiments, the ports of the liquid collector 6 may be staggeredly arranged with respect to the ports of the liquid distributor 5 along the column direction, so as to facilitate communication between the ports of the liquid collector 6 and the corresponding guide tubes 7 and between the ports of the liquid distributor 5 and the corresponding guide tubes 7.

In some embodiments, as shown in the figures, the first electronic components 1 are arranged in four rows and two columns (i.e., the number of the first electronic components 1 is eight), and the second electronic components 2 are arranged in four rows and one column (i.e., the number of the second electronic components 2 is four). The first cooling plates 3 corresponding to the first electronic component 1 in each row are arranged in parallel, and correspondingly, four pairs of first liquid distribution port and first liquid collection port are provided. The second cooling plates 4 corresponding to the second electronic components 2 in the one column are connected in series, and correspondingly, one pair of second liquid distribution port and second liquid collection port is provided.

Specifically, the liquid distributor 5 may be provided with five ports, namely, the first liquid distribution port A1, the first liquid distribution port A2, the first liquid distribution port A3, the first liquid distribution port A4, and the second liquid distribution port. The liquid collector 6 is provided with five ports, namely, the second liquid collection port, the first liquid collection port B1, the first liquid collection port B2, the first liquid collection port B3, and the first liquid collection port B4. Along a liquid flowing direction in the liquid distributor, on the liquid distributor, the first liquid distribution port A1 corresponds to the first cooling plates 3 of the first row, the first liquid distribution port A2 corresponds to the first cooling plates 3 of the second row, the first liquid distribution port A3 corresponds to the first cooling plates 3 of the third row, the first liquid distribution port A4 corresponds to the first cooling plates 3 of the fourth row, and the second liquid distribution port is connected to the inlet of the second cooling plate 4 of the fourth row. Along the liquid flowing direction in the liquid distributor, on the liquid collector, the second liquid collection port is connected to the outlet of the second cooling plate 4 of the first row, the first liquid collection port B1 corresponds to the first cooling plates 3 of the first row, the first liquid collection port B2 corresponds to the first cooling plates 3 of the second row, the first liquid collection port B3 corresponds to the first cooling plates 3 of the third row, and the first liquid collection port B4 corresponds to the first cooling plates 3 of the fourth row. Along the liquid flowing direction of liquid in the liquid distributor, the five ports of the liquid distributor are arranged staggeredly with respect to the five ports of the liquid collector, and the five ports of the liquid distributor and the five ports of the liquid collector face the same side. The liquid distributor and the liquid collector are arranged side by side along the up-down direction, which is perpendicular to both the extension direction of the liquid distributor and the row direction of the first electronic components and the second electronic components 2.

In some embodiments, the first cooling plates 3 and the second cooling plates 4 may be in communication with the liquid collector 6 and the liquid distributor 5 through guide tubes 7. The first liquid distribution port, the first liquid collection port, the second liquid distribution port, and the second liquid collection port are each in communication with the corresponding guide tube 7 through a shut-off assembly 8. The shut-off assembly 8 includes a first connection device and a second connection device that can be detached and separated from each other. The first connection device is arranged at an orifice of the corresponding guide tube 7 and blocks the guide tube 7 when being disassembled from the second connection device. The second connection device is arranged at the liquid distributor 5 or the liquid collector 6 and blocks the corresponding port when being disassembled from the first connection device. As such, during disassembling, it only needs to remove the shut-off assembly 8 on the corresponding pair of liquid distribution port and liquid collection port.

Specifically, the first connection device and the second connection device each includes a connecting seat and a valve core, a flow passage is provided inside the connecting seat and a pushing block is provided on the connecting seat. The valve core is slidably located in the connecting seat, and the valve core is provided with a through hole and a groove. The pushing block on the connecting seat of the first connection device is used to be inserted into the groove of the valve core of the second connection device, and the pushing block on the connecting seat of the second connection device is used to be inserted into the groove of the valve core of the first connection device. The first connection device and the second connection device slide relative to each other so that the two through holes and the corresponding flow passages are aligned with each other for communication or staggered with respect to each other for blocking. When the two pushing blocks drive the two valve cores to slide to reach the blocking position, the two pushing blocks are in snap-fit with the corresponding connecting seats. Specifically, the two pushing blocks drive the two valve cores to slide, so that the through hole in the valve core of the first connection device is aligned with the flow passage on the connection seat of the first connection device; meanwhile, the through hole on the valve core of the second connection device is aligned with the flow passage on the connection seat of the second connection device, and the flow passage of the first connection device is aligned with the flow passage of the second connection device. In that case, the first connection device and the second connection device are in communication, and the pushing block of the first connection device is in snap-fit with the connection seat of the second connection device, and the pushing block of the second connection device is in snap-fit with the connection seat of the first connection device, achieving the connection between the first connection device and the second connection device. When the first connection device and the second connection device slide in opposite directions, the two pushing blocks drive the two valve cores to slide, so that the through hole of the valve core of the first connection device is made staggeredly with respect to the flow passage of the connection seat of the first connection devices for closing the flow passage, and the through hole of the valve core of the second connection device is made staggeredly with respect to the flow passage of the connection seat of the second connection device for closing the flow passage. The pushing block of the first connection device can be pulled out from the second connection device, and the pushing block of the second connection device can be pulled out from the first connection device, thereby achieving disassembly and separation.

In some embodiments, the first connection device may include a switch valve and one joint of a quick coupling at one end, and the second connection device may include a switch valve and the other joint of the quick coupling at the other end.

In some embodiments, a collector is further included. A first detector is provided at the guide tube 7, which is extended along the guide tube 7 to detect whether leakage occurs at the guide tube 7. A second detector is provided on the cooling plate to detect whether leakage occurs in the cooling plate. The first and second detectors, corresponding to the guide tubes and the cooling plates which are connected between a corresponding pair of liquid collection port and liquid distribution port, are connected in series to form a circuit. Specifically, the first detectors and the second detectors, corresponding to the guide tubes and the first cooling plates which are connected between a corresponding pair of first liquid collection port and first liquid distribution port, are connected in series to form a circuit; the first detectors and the second detectors, corresponding to the guide tubes and the second cooling plates which are connected between the second liquid collection port and the second liquid distribution port, are connected in series to form another circuit. The collector is used to collect an on/off state of each circuit.

For example, the two first cooling plates 3 in the first row, namely one first cooling plate 3 and another first cooling plate 3, are connected in parallel between a corresponding pair of first liquid distribution port and first liquid collection port. Correspondingly, four guide tubes 7 are provided, namely a first guide tube, a second guide tube, a third guide tube and a fourth guide tube. The first guide tube 7 is connected between the corresponding first liquid distribution port and a first tee joint, and the first tee joint is in communication with the inlet of the one first cooling plate 3; the second guide tube 7 is connected between the first tee joint and the inlet of the another second first cooling plate 3; and the third guide tube 7 is connected between the outlet of the another second first cooling plate 3 and the second tee joint; the second tee joint is in communication with the outlet of the one first cooling plate 3; and a fourth guide tube 7 is connected between the second tee joint and the corresponding first liquid collection port. The first to fourth guide tubes 7 are provided with a first detector D11, a first detector D12, a first detector D13 and a first detector D14, respectively, where the one first cooling plate is provided with a second detector D21 and the another second cooling plate is provided with a second detector D22.

The connection in series may be as follows: a first type of connection, the first detector D11, the second detector D21, the first detector D12, the second detector D22, the first detector D13, and the first detector D14 are sequentially connected in series; a second type of connection, the first detector D11, the first detector D12, the second detector D22, the first detector D13, the second detector D21, and the first detector D14 are sequentially connected in series.

It should be noted that the specific connection between the two detectors can be determined according to the actual detector circuit structure. Generally, the detector mainly includes two detection lines, where, in case that there is liquid between the two lines, the two lines are conducted by the liquid. The detectors are connected in series, that is, the two detection lines in the detectors are respectively connected in sequence.

In some embodiments, a protective outer tube may be sleeved on the outer side of the guide tube 7, and the first detector is positioned between the guide tube 7 and the protective outer tube to restrain the liquid leaked from the guide tube 7 by the protective outer tube.

In some embodiments, the cooling plate may also be provided with a leakage collection device. Specifically, the leakage collection device includes a trough body 9 with an upward opening and a cover 10 for covering the opening of the trough body 9. The cooling plate includes a heated plate and a cover plate. A window is provided at a bottom of trough body 9, and a periphery of the heated plate is sealedly connected to a periphery of the window. A gap is formed between a periphery of the cover plate and inner walls of the trough body 9, so that a liquid leaking from a sealing joint between the heated plate and the cover plate can flow to a side of the cover plate away from the heated plate through the gap. In addition, since the periphery of the heated plate is sealedly connected to the periphery of the window, the liquid leaking from the sealing joint between the heated plate and the cover plate cannot leak out through the window. Correspondingly, the second detector may be a sheet-like detector mounted on the cover plate, where the sheet-like detector may be obtained by the strip-like detectors being provided in parallel.

In some embodiments, a collection box 11 may be further provided, and the shut-off assembly 8, the liquid distributor 5, and the liquid collector 6 are all provided inside the collection box 11. A side, away from the first electronic components, of an inner lower surface of the collection box 11 is inclined downwards, so that the liquid can be accumulated at one side, and a detector for detecting leakage, such as a strip-like detector, may be provided on this side.

In some embodiments, as described above, the four rows of first cooling plates 3 form four detection lines, respectively, the one column of second cooling plates 4 form one detection line, and the collection box 11 forms one detection line separately, and thus there are totally six detection lines. In this case, the collector may be embodied as a detection unit including multiple detectors for obtaining the on/off state of the detection lines respectively, or may be an integrated detection structure, which is provided with inlet port for detecting the on/off state of the detection lines respectively.

The above embodiments in this specification are described in a progressive manner. Each of the embodiments is mainly focused on describing its differences from other embodiments, and references may be made among these embodiments with respect to the same or similar portions among these embodiments.

Based on the above description of the disclosed embodiments, those skilled in the art are capable of carrying out or using the present application. It is obvious for those skilled in the art to make many modifications to these embodiments. The general principle defined herein may be applied to other embodiments without departing from the spirit or scope of the present application. Therefore, the present application is not limited to the embodiments illustrated herein, but should be defined by the broadest scope consistent with the principle and novel features disclosed herein.

1. A server, comprising a liquid cooling system, a plurality of first electronic components each configured to have a first function, and a plurality of second electronic components each configured to have a second function, wherein
the liquid cooling system comprises a plurality of first cooling plates in one-to-one correspondence with the plurality of first electronic components, a plurality of second cooling plates in one-to-one correspondence with the plurality of second electronic components, a liquid distributor, and a liquid collector;
each of the plurality of first electronic components is fitted against a corresponding one of the plurality of first cooling plates, and each of the plurality of second electronic components is fitted against a corresponding one of the plurality of second cooling plates; and wherein
at least two of the plurality of first cooling plates are connected in series and/or in parallel between a first liquid distribution port of the liquid distributor and a first liquid collection port of the liquid collector, and at least two of the plurality of second cooling plates are connected in series and/or in parallel between a second liquid distribution port of the liquid distributor and a second liquid collection port of the liquid collector.

2. The server according to claim 1, wherein
the plurality of first electronic components are arranged in a plurality of rows and/or a plurality of columns, the first cooling plates in each of the plurality of rows are arranged in series or in parallel, and the first cooling plates in each of the plurality of columns are arranged in series or in parallel; and/or
the plurality of second electronic components are arranged in a plurality of rows and/or a plurality of columns, the second cooling plates in each of the plurality of rows are arranged in series or in parallel, and the second cooling plates in each of the plurality of columns are arranged in series or in parallel.

3. The server according to claim 1, wherein
the number of the first liquid distribution port is plural, and the number of the first liquid collection port is plural, each of the first liquid distribution ports together with a corresponding one of the first liquid collection ports form a pair of first liquid distribution port and first liquid collection port;
the plurality of first electronic components are arranged in a plurality of rows and a plurality of columns, the first cooling plates in each of the plurality of rows are arranged in parallel, the first cooling plates in each of the plurality of rows are in communication with the corresponding pair of first liquid distribution port and first liquid collection port;
the plurality of second electronic components are arranged in one column, and the plurality of second cooling plates are connected in series, wherein the plurality of first electronic components are GPUs, and the plurality of second electronic components are switches.

4. The server according to claim 3, wherein
the liquid collector extends in a column direction and is provided with a plurality of ports in sequence, to serve as the first liquid collection ports and the second liquid collection port respectively;
the liquid distributor extends in the column direction and is provided with a plurality of ports in sequence, to serve as the first liquid distribution ports and the second liquid distribution port respectively; and wherein
each of the first liquid collection ports and a corresponding one of the first liquid distribution ports are connected to a corresponding row of first cooling plates of the plurality of first cooling plates.

5. The server according to claim 4, wherein both the liquid collector and the liquid distributor are arranged at sides of the plurality of second electronic components away from the plurality of first electronic components, and the plurality of ports of the liquid collector are arranged staggeredly with respect to the plurality of ports of the liquid distributor along the column direction.

6. The server according to claim 1, wherein
the plurality of first cooling plates and the plurality of second cooling plates are in communication with the liquid collector and the liquid distributor through a plurality of guide tubes, and each of the first liquid distribution port, the first liquid collection port, the second liquid distribution port, and the second liquid collection port is in communication with the corresponding one of the plurality of guide tubes through a shut-off assembly;
the shut-off assembly comprises a first connection device and a second connection device that are detachable and separatable from each other; the first connection device is arranged at an orifice of the corresponding one of the plurality of guide tubes, and is configured to block the guide tube when being disassembled from the second connection device; and the second connection device is arranged at the liquid distributor or the liquid collector, and is configured to block the corresponding port when being disassembled from the first connection device.

7. The server according to claim 6, wherein
each of the plurality of guide tubes is provided with a first detector extending along the guide tube, to detect leakage at the guide tube; and each of the plurality of first cooling plates and the plurality of second cooling plates is provided with a second detector, to detect leakage at the corresponding first cooling plate or the corresponding second cooling plate;
a part of the plurality of first detectors and a part of the plurality of second detectors, corresponding to a part of the plurality of guide tubes and a part of the plurality of first cooling plates which are connected between the first liquid collection port and the first liquid distribution port, are connected in series to form a circuit;
another part of the plurality of first detectors and another part of the plurality of second detectors, corresponding to another part of the plurality of guide tubes and a part of the plurality of second cooling plates which are connected between the second liquid collection port and the second liquid distribution port, are connected in series to form another circuit; and
the server further comprises a collector for collecting an on/off state of each of the circuit and the another circuit.

8. The server according to claim 7, wherein a protective outer tube is sleeved on an outer side of each of the plurality of guide tubes, and the corresponding first detector is positioned between the guide tube and the protective outer tube.

9. The server according to claim 8, further comprising a trough body with an upward opening, and a cover for covering the opening of the trough body, wherein
each of the plurality of first cooling plates and the plurality of second cooling plates comprises a heated plate and a cover plate, a window is provided at a bottom of the trough body, and a periphery of the heated plate is sealedly connected to a periphery of the window;
a gap is formed between a periphery of the cover plate and inner walls of the trough body, to allow a liquid leaking from a sealing joint between the heated plate and the cover plate to flow to one side of the cover plate away from the heated plate through the gap; and wherein
the second detector is a sheet-like detector arranged on the cover plate.

10. The server according to claim 9, further comprising a collection box, wherein
the shut-off assembly, the liquid distributor, and the liquid collector are arranged inside the collection box; and
a side, away from the plurality of first electronic components, of an inner lower surface of the collection box is inclined downwards and is provided with a detector for detecting leakage.

11. The server according to claim 2, wherein
the plurality of first cooling plates and the plurality of second cooling plates are in communication with the liquid collector and the liquid distributor through a plurality of guide tubes, and each of the first liquid distribution port, the first liquid collection port, the second liquid distribution port, and the second liquid collection port is in communication with the corresponding one of the plurality of guide tubes through a shut-off assembly;
the shut-off assembly comprises a first connection device and a second connection device that are detachable and separatable from each other; the first connection device is arranged at an orifice of the corresponding one of the plurality of guide tubes, and is configured to block the guide tube when being disassembled from the second connection device; and the second connection device is arranged at the liquid distributor or the liquid collector, and is configured to block the corresponding port when being disassembled from the first connection device.

12. The server according to claim 3, wherein
the plurality of first cooling plates and the plurality of second cooling plates are in communication with the liquid collector and the liquid distributor through a plurality of guide tubes, and each of the first liquid distribution port, the first liquid collection port, the second liquid distribution port, and the second liquid collection port is in communication with the corresponding one of the plurality of guide tubes through a shut-off assembly;
the shut-off assembly comprises a first connection device and a second connection device that are detachable and separatable from each other; the first connection device is arranged at an orifice of the corresponding one of the plurality of guide tubes, and is configured to block the guide tube when being disassembled from the second connection device; and the second connection device is arranged at the liquid distributor or the liquid collector, and is configured to block the corresponding port when being disassembled from the first connection device.

13. The server according to claim 4, wherein
the plurality of first cooling plates and the plurality of second cooling plates are in communication with the liquid collector and the liquid distributor through a plurality of guide tubes, and each of the first liquid distribution port, the first liquid collection port, the second liquid distribution port, and the second liquid collection port is in communication with the corresponding one of the plurality of guide tubes through a shut-off assembly;
the shut-off assembly comprises a first connection device and a second connection device that are detachable and separatable from each other; the first connection device is arranged at an orifice of the corresponding one of the plurality of guide tubes, and is configured to block the guide tube when being disassembled from the second connection device; and the second connection device is arranged at the liquid distributor or the liquid collector, and is configured to block the corresponding port when being disassembled from the first connection device.

14. The server according to claim 5, wherein
the plurality of first cooling plates and the plurality of second cooling plates are in communication with the liquid collector and the liquid distributor through a plurality of guide tubes, and each of the first liquid distribution port, the first liquid collection port, the second liquid distribution port, and the second liquid collection port is in communication with the corresponding one of the plurality of guide tubes through a shut-off assembly;
the shut-off assembly comprises a first connection device and a second connection device that are detachable and separatable from each other; the first connection device is arranged at an orifice of the corresponding one of the plurality of guide tubes, and is configured to block the guide tube when being disassembled from the second connection device; and the second connection device is arranged at the liquid distributor or the liquid collector, and is configured to block the corresponding port when being disassembled from the first connection device.
